(19) United States
(12) Patent Application Publication
(10) Pub. No.: US 2016/0196996 A1
(43) Pub. Date: Jul. 7, 2016

(54) ADSORPTION DEVICE AND CONTROL METHOD THEREOF

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Yangkun JING, Beijing (CN); Xing WU, Beijing (CN)

(21) Appl. No.: 14/802,646

(22) Filed: Jul. 17, 2015

(30) Foreign Application Priority Data
Jan. 4, 2015 (CN) 201510001892.1

(51) Int. Cl. H01L 21/683; H01J 37/32

(52) U.S. Cl. CPC H01L 21/6833; H01J 37/32715

(57) ABSTRACT

The present invention provides an adsorption device and a control method thereof. The adsorption device includes a loading module, a power supply module, a temperature detection module and a voltage control module, wherein the loading module is used for adsorbing and loading a substrate, the power supply module is used for applying a DC voltage to the loading module to enable the loading module to generate an adsorption force, the temperature detection module is used for detecting the temperature of the loading module, and the voltage control module is used for controlling the DC voltage applied to the loading module from the power supply module according to the temperature detected by the temperature detection module, so as to keep the adsorption force as a constant value.

### FIELD OF THE INVENTION

The present invention relates to the technical field of semiconductor processing, and particularly relates to an adsorption device and a control method thereof.

### BACKGROUND OF THE INVENTION

In the prior art, when an adsorption device is used for adsorbing a substrate to perform a plasma process, the temperature of the adsorption device usually rises due to the action of the generated plasma. In addition, in a series of processing technology having a plurality of procedures, the temperature of the substrate may change greatly among the procedures, so that the temperature of the adsorption device changes greatly sometimes. The temperature change of the adsorption device will influence the resistivity of the adsorption device, for example, when the temperature becomes higher, the resistivity of the adsorption device becomes lower, and when the temperature becomes lower, the resistivity of the adsorption device becomes higher. The resistivity of the adsorption device changes violently according to the temperature, resulting in that the adsorption force of the adsorption device changes according to the temperature change.

### SUMMARY OF THE INVENTION

To solve the above problem, the present invention provides an adsorption device and a control method thereof, which are used for solving the problem in the prior art that the temperature change of the adsorption device results in the change of the adsorption force thereof.

In view of this, the present invention provides an adsorption device, including a loading module, a power supply module, a temperature detection module and a voltage control module, wherein the loading module is used for adsorbing and loading a substrate; the power supply module is electrically connected to the loading module and is used for applying a DC voltage to the loading module to enable the loading module to generate an adsorption force; the temperature detection module is coupled to the loading module and is used for detecting the temperature of the loading module; the voltage control module is respectively coupled to the power supply module and the temperature detection module and is used for controlling the DC voltage applied to the loading module from the power supply module according to the temperature detected by the temperature detection module, so as to keep the adsorption force as a constant value.

Optionally, the voltage control module includes a reversing module, and the reversing module is used for reversing the polarity of the DC voltage applied to the loading module from the power supply module, so as to drive the loading module to generate an acting force in a direction opposite to the direction of the adsorption force.

Optionally, the voltage control module is used for controlling the power supply module to decrease the DC voltage when the temperature detected by the temperature detection module is higher than a preset temperature, and controlling the power supply module to increase the DC voltage when the temperature detected by the temperature detection module is lower than the preset temperature.

Optionally, the voltage control module further includes a time control module, and the time control module is used for, when the reserving module reverses the polarity of the DC voltage applied by the power supply module, controlling the time for applying the polarity-reversed DC voltage to the loading module from the power supply module according to the temperature detected by the temperature detection module, in order to neutralize accumulated charges on the loading module.

Optionally, the time control module is used for, when the temperature detected by the temperature detection module is higher than the preset temperature, controlling the time for applying the polarity-reversed DC voltage to the loading module from the power supply module to be longer than a preset time, and when the temperature detected by the temperature detection module is lower than the preset temperature, controlling the time for applying the polarity-reversed DC voltage to the loading module from the power supply module to be shorter than the preset time.

The present invention further provides a control method of an adsorption device, the adsorption device includes a loading module used for adsorbing and loading a substrate, a power supply module electrically connected to the loading module and used for applying a DC voltage to the loading module to enable the loading module to generate an adsorption force, a temperature detection module coupled to the loading module, and a voltage control module respectively coupled to the power supply module and the temperature detection module, wherein the control method includes steps of: detecting, by the temperature detection module, the temperature of the loading module; and controlling, by the voltage control module, the DC voltage applied to the loading module from the power supply module according to the temperature detected by the temperature detection module, so as to keep the constancy of the adsorption force.

Optionally, the voltage control module further includes a reversing module, and the control method further includes: reversing, by the reversing module, the polarity of the DC voltage applied to the loading module from the power supply module, so as to drive the loading module to generate an acting force in a direction opposite to the direction of the adsorption force.

Optionally, the step of controlling, by the voltage control module, the DC voltage applied from the power supply module according to the temperature detected by the temperature detection module includes: controlling, by the voltage control module, the power supply module to decrease the DC voltage when the temperature detected by the temperature detection module is higher than a preset temperature; and controlling, by the voltage control module, the power supply module to increase the DC voltage when the temperature detected by the temperature detection module is lower than the preset temperature.

Optionally, the voltage control module further includes a time control module, and the control method further includes a step of: when the reserving module reverses the polarity of the DC voltage applied from the power supply module, controlling, by the time control module, the time for applying the polarity-reversed DC voltage to the loading module from the power supply module according to the temperature detected by the temperature detection module, in order to neutralize accumulated charges on the loading module.

Optionally, the step of controlling, by the time control module, the time for applying the polarity-reversed DC voltage from the power supply module includes: when the temperature detected by the temperature detection module is higher than the preset temperature, controlling, by the time control module, the time for applying the polarity-reversed DC voltage to be longer than a preset time; and when the temperature detected by the temperature detection module is lower than the preset temperature, controlling, by the time control module, the time for applying the polarity-reversed DC voltage to be shorter than the preset time.

The present invention has the following beneficial effects.

In the adsorption device and the control method thereof provided by the present invention, the adsorption device includes the loading module, the power supply module, the temperature detection module and the voltage control module, the loading module is used for adsorbing and loading the substrate, the power supply module is used for applying the DC voltage to the loading module to enable the loading module to generate the adsorption force, the temperature detection module is used for detecting the temperature of the loading module, the voltage control module is used for controlling the DC voltage applied by the power supply module according to the temperature detected by the temperature detection module, so as to keep the adsorption force as the constant value, such that it is ensured that the adsorption force of the adsorption device does not change violently with the temperature change of the adsorption device, and the change of the adsorption force caused by the temperature change of the adsorption device is avoided.

### BRIEF DESCRIPTION OF THE DRAWINGS

FIG. 1 is a schematic diagram of a structure of an adsorption device provided by a first embodiment of the present invention;

FIG. 2 is a schematic diagram of a preferred structure of a voltage control module in the first embodiment of the present invention;

FIG. 3 is a flowchart of a control method of an adsorption device provided by a second embodiment of the present invention.

### DETAILED DESCRIPTION OF THE EMBODIMENTS

In order that those skilled in the art can better understand the technical solutions of the present invention, a detailed description on the adsorption device and the control method thereof provided by the present invention will be given below in conjunction with the accompanying drawings.

### First Embodiment

FIG. 1 is a schematic diagram of a structure of an adsorption device provided by the first embodiment of the present invention. As shown in FIG. 1, the adsorption device includes a loading module 101, a power supply module 102, a temperature detection module 103 and a voltage control module 104. The loading module 101 is respectively connected with the power supply module 102 and the temperature detection module 103, the power supply module 102 is connected with the voltage control module 104, and the temperature detection module 103 is connected with the voltage control module 104. The loading module 101 is used for adsorbing and loading a substrate 105, the power supply module 102 is used for applying a DC voltage to the loading module 101 to enable the loading module 101 to generate an adsorption force, the temperature detection module 103 is used for detecting the temperature of the loading module 101, and the voltage control module 104 is used for controlling the DC voltage output by the power supply module 102 according to the temperature detected by the temperature detection module 103, so as to keep the adsorption force as a constant value.

When the adsorption device in this embodiment is used in a display device processing system, the display device processing system includes a vacuum chamber, and the adsorption device is arranged in the vacuum chamber. The display device processing system generates plasma for processing the substrate 105 loaded on the loading module 101. The loading module 101 includes a medium body made of an insulator material and an electrode made of a conductive material, the electrode is connected with the power supply module 102, and the power supply module 102 applies the DC voltage to the electrode to enable the loading module 101 to generate the adsorption force, so as to fix the substrate 105 on the loading module 101. When the substrate 105 is fixed on the loading module 101, the display device processing system starts to generate the plasma for processing the substrate 105, and at this time, the temperature of the loading module 101 changes. The temperature detection module 103 detects the temperature of the loading module 101. When the detected temperature is higher than a preset temperature, the voltage control module 104 controls the power supply module 102 to decrease the DC voltage, and when the detected temperature is lower than the preset temperature, the voltage control module 104 controls the power supply module 102 to increase the DC voltage. The voltage control module 104 implements the above control operations to keep the adsorption force generated by the loading module 101 to be constant, such that the adsorption force of the adsorption device will not change violently as the temperature change of the adsorption device, and the problem that the adsorption force changes as a result of the temperature change in the adsorption device in the prior art is avoided.

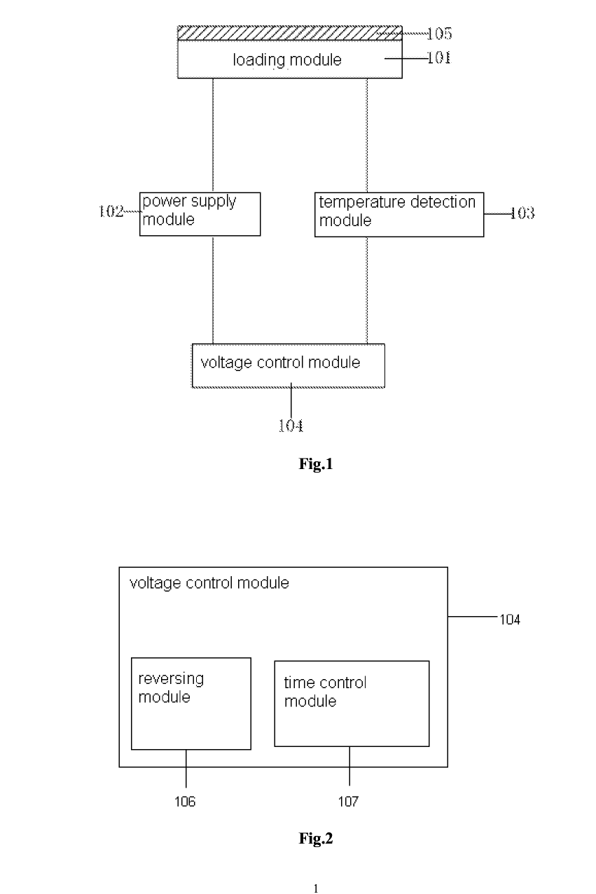

In practical application, as shown in FIG. 2, the voltage control module 104 further includes a reversing module 106. The reversing module 106 is used for reversing the polarity of the DC voltage applied by the power supply module 102 to the loading module 101, so as to drive the loading module 101 to generate an acting force in a direction opposite to the direction of the adsorption force. By means of the above manner, the substrate 105 can be removed from the loading module 101 without barrier, so that the phenomenon that the substrate 105 cannot be removed from the loading module 101 due to an overlarge adsorption force caused by the temperature change of the loading module 101 is avoided.

Specifically, when the processing technology of the substrate 105 is finished, the reversing module 106 reverses the polarity of the DC voltage output from the power supply module 102, in order to generate the acting force in a direction opposite to the direction of the adsorption force by the loading module 101.

Preferably, as shown in FIG. 2, the voltage control module 104 further includes a time control module 107. The time control module 107 is used for, when the reserving module 106 reverses the polarity of the DC voltage output by the power supply module 102, controlling the time for applying the polarity-reversed DC voltage to the loading module 101 from the power supply module 102 according to the temperature detected by the temperature detection module 103, in order to neutralize accumulated charges on the loading module 101.

Specifically, when the processing technology of the substrate 105 is finished, the reversing module 106 controls the power supply module 102 to apply the polarity-reversed DC voltage to the loading module 101, to discharge (neutralize) the charges accumulated on the loading module 101. At this time, the temperature detection module 103 detects the temperature of the loading module 101, if the detected temperature is higher than the preset temperature, the time control module 107 controls the time for applying the polarity-reversed DC voltage to the loading module 101 from the power supply module 102 to be longer than a preset time, and if the detected temperature is lower than the preset temperature, the time control module 107 controls the time for applying the polarity-reversed DC voltage to the loading module 101 from the power supply module 102 to be shorter than the preset time. Within a particular time, the power supply module 102 discharges (neutralizes) the charges accumulated on the loading module 101, so that the adsorption force generated by the loading module 101 becomes zero, and accordingly the substrate 105 can be removed from the loading module 101 without barrier. The adsorption device in this preferred embodiment can avoid the phenomenon that the substrate 105 cannot be removed from the loading module 101 due to the overlarge adsorption force caused by the temperature change of the loading module 101.

The adsorption device provided by this embodiment includes the loading module 101, the power supply module 102, the temperature detection module 103 and the voltage control module 104, the loading module 101 is used for adsorbing and loading the substrate 105, the power supply module 102 is used for applying the DC voltage to the loading module 101 to enable the loading module 101 to generate the adsorption force, the temperature detection module 103 is used for detecting the temperature of the loading module 101, the voltage control module 104 is used for controlling the DC voltage applied by the power supply module 102 to the loading module 101 according to the temperature detected by the temperature detection module 103, so as to keep the adsorption force as the constant value, such that the adsorption force of the adsorption device does not change violently with the temperature change of the adsorption device, and the change of the adsorption force caused by the temperature change of the adsorption device is avoided.

### Second Embodiment

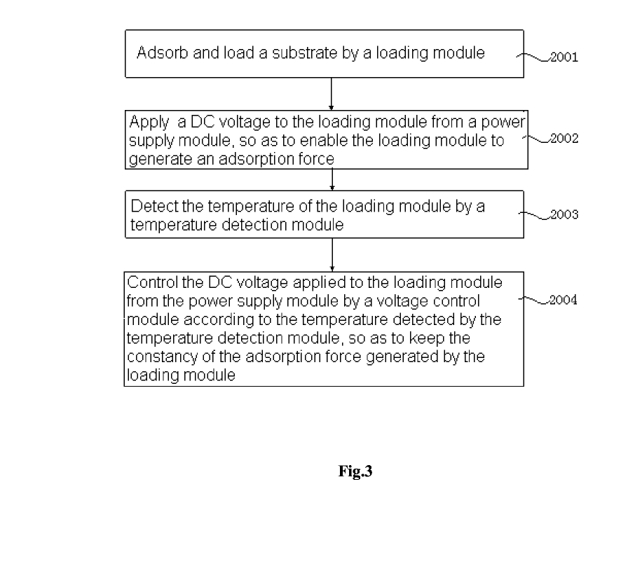

FIG. 3 is a flowchart of a control method of an adsorption device provided by the second embodiment of the present invention. As shown in FIG. 3, the working process of the adsorption device includes: step 2001, adsorbing and loading, by a loading module, a substrate; step 2002. applying, by a power supply module, a DC voltage to the loading module to enable the loading module to generate an adsorption force.

Specifically, when the control method of the adsorption device in this embodiment is used in a display device processing system, the display device processing system includes a vacuum chamber, and the adsorption device is arranged in the vacuum chamber. The display device processing system generates plasma for processing the substrate loaded on the loading module. The loading module includes a medium body made of an insulator material and an electrode made of a conductive material, the electrode is connected with the power supply module, and the power supply module applies the DC voltage to the electrode to enable the loading module to generate the adsorption force, so as to fix the substrate on the loading module.

The control method of the adsorption device provided by the second embodiment of the present invention is used for controlling via a temperature detection module and a voltage control module. Specifically, the control method includes: step 2003. detecting, by the temperature detection module, the temperature of the loading module; step 2004. controlling, by the voltage control module, the DC voltage applied by the power supply module to the loading module according to the temperature detected by the temperature detection module, so as to keep the constancy of the adsorption force generated by the loading module.

In this embodiment, when the substrate is fixed on the loading module, the display device processing system starts to generate the plasma for processing the substrate, and at this time, the temperature of the loading module changes. According to the control method provided by the present invention, the temperature detection module is used for detecting the temperature of the loading module, when the detected temperature is higher than a preset temperature, the voltage control module controls the power supply module to decrease the DC voltage, and when the detected temperature is lower than the preset temperature, the voltage control module controls the power supply module to increase the DC voltage. The voltage control module implements the above control operations to keep the adsorption force generated by the loading module as the constant value, such that the adsorption force of the adsorption device will not change violently with the temperature change of the adsorption device, and the problem that the adsorption force changes as a result of the temperature change in the adsorption device in the prior art is avoided.

Preferably, the control method of the adsorption device provided by the second embodiment of the present invention can be further used for controlling via a reversing module and a time control module configured in the voltage control module. Specifically, when the processing technology of the substrate is finished, the reversing module is used for reversing the polarity of the DC voltage applied by the power supply module to the loading module, in order to enable the loading module to generate an acting force in a direction opposite to the direction of the adsorption force. Further, the control method in this embodiment is further used for controlling the application time of the reversed DC voltage through the time control module. Specifically, the time control module is used for, when the reserving module reverses the polarity of the DC voltage applied from the power supply module, controlling the time for applying the polarity-reversed DC voltage to the loading module from the power supply module according to the temperature detected by the temperature detection module, in order to neutralize accumulated charges on the loading module.

By means of the above preferred control method, the substrate can be removed from the loading module without barrier, so that the phenomenon that the substrate cannot be removed from the loading module due to an overlarge adsorption force caused by the temperature change of the loading module is avoided.

In addition, the above preferred control method is used for controlling the application time of the reversed voltage via the time control module. If the temperature of the loading module detected by the temperature detection module is higher than the preset temperature, the time control module controls the application time of the polarity-reversed DC voltage to be longer than a preset time, and if the detected temperature of the loading module is lower than the preset temperature, the time control module controls the application time of the polarity-reversed DC voltage to be shorter than the preset time. Within a particular time, the power supply module discharges (neutralizes) the charges accumulated on the loading module, so that the adsorption force generated by the loading module becomes zero, and accordingly the substrate can be removed from the loading module without barrier. The control method in this preferred embodiment can be used for avoiding the phenomenon that the substrate cannot be removed from the loading module 101 due to the overlarge adsorption force caused by the temperature change of the loading module.

In the control method of the adsorption device provided by this embodiment, the temperature detection module is used for detecting the temperature of the loading module, and the voltage control module is used for controlling the DC voltage applied by the power supply module to the loading module according to the temperature detected by the temperature detection module, so as to keep the adsorption force as the constant value, such that it is ensured that the adsorption force of the adsorption device does not change violently with the temperature change of the adsorption device, and the change of the adsorption force caused by the temperature change of the adsorption device is avoided.

It can be understood that, the foregoing implementations are merely exemplary implementations used for illustrating the principle of the present invention, but the present invention is not limited hereto. Those of ordinary skill in the art can make various variations and improvements without departing from the spirit and essence of the present invention, and these variations and improvements shall fall within the protection scope of the present invention.

1. An adsorption device, comprising a loading module, a power supply module, a temperature detection module and a voltage control module, wherein
the loading module is used for adsorbing and loading a substrate;
the power supply module is electrically connected to the loading module and is used for applying a DC voltage to the loading module to enable the loading module to generate an adsorption force;
the temperature detection module is coupled to the loading module and is used for detecting the temperature of the loading module;
the voltage control module is respectively coupled to the power supply module and the temperature detection module and is used for controlling the DC voltage applied to the loading module from the power supply module according to the temperature detected by the temperature detection module, so as to keep the adsorption force as a constant value.

2. The adsorption device of claim 1, wherein the voltage control module is used for, when the temperature detected by the temperature detection module is higher than a preset temperature, controlling the power supply module to decrease the DC voltage, and when the temperature detected by the temperature detection module is lower than the preset temperature, controlling the power supply module to increase the DC voltage.

3. The adsorption device of claim 1, wherein the voltage control module comprises a reversing module, and the reversing module is used for reversing the polarity of the DC voltage applied to the loading module from the power supply module, so as to drive the loading module to generate an acting force in a direction opposite to the direction of the adsorption force.

4. The adsorption device of claim 3, wherein the voltage control module further comprises a time control module, and the time control module is used for, when the reserving module reverses the polarity of the DC voltage applied by the power supply module, controlling the time for applying the polarity-reversed DC voltage to the loading module from the power supply module according to the temperature detected by the temperature detection module, in order to neutralize accumulated charges on the loading module.

5. The adsorption device of claim 4, wherein the time control module is used for, when the temperature detected by the temperature detection module is higher than the preset temperature, controlling the time for applying the polarity-reversed DC voltage to the loading module from the power supply module to be longer than a preset time, and when the temperature detected by the temperature detection module is lower than the preset temperature, controlling the time for applying the polarity-reversed DC voltage to the loading module from the power supply module to be shorter than the preset time.

6. A control method of an adsorption device, the adsorption device comprises a loading module used for adsorbing and loading a substrate, a power supply module electrically connected to the loading module and used for applying a DC voltage to the loading module to enable the loading module to generate an adsorption force, a temperature detection module coupled to the loading module, and a voltage control module respectively coupled to the power supply module and the temperature detection module,
wherein the control method comprises steps of:
detecting, by the temperature detection module, the temperature of the loading module; and
controlling, by the voltage control module, the DC voltage applied to the loading module from the power supply module according to the temperature detected by the temperature detection module, so as to keep the constancy of the adsorption force.

7. The control method of the adsorption device of claim 6, wherein the step of controlling, by the voltage control module, the DC voltage applied from the power supply module to the loading module according to the temperature detected by the temperature detection module comprises:
controlling, by the voltage control module, the power supply module to decrease the DC voltage when the temperature detected by the temperature detection module is higher than a preset temperature; and
controlling, by the voltage control module, the power supply module to increase the DC voltage when the temperature detected by the temperature detection module is lower than the preset temperature.

8. The control method of the adsorption device of claim 6, wherein the voltage control module further comprises a reversing module, and the control method further comprises:
reversing, by the reversing module, the polarity of the DC voltage applied to the loading module from the power supply module, so as to drive the loading module to generate an acting force in a direction opposite to the direction of the adsorption force.

9. The control method of the adsorption device of claim 8, wherein the voltage control module further comprises a time control module, and the control method further comprises a step of:
when the reserving module reverses the polarity of the DC voltage applied from the power supply module, controlling, by the time control module, the time for applying the polarity-reversed DC voltage to the loading module from the power supply module according to the temperature detected by the temperature detection module, in order to neutralize accumulated charges on the loading module.

10. The control method of the adsorption device of claim 9, wherein the step of controlling, by the time control module, the time for applying the polarity-reversed DC voltage to the loading module from the power supply module according to the temperature detected by the temperature detection module comprises:
when the temperature detected by the temperature detection module is higher than the preset temperature, controlling, by the time control module, the time for applying the polarity-reversed DC voltage by the power supply moduleto the loading module to be longer than a preset time; and
when the temperature detected by the temperature detection module is lower than the preset temperature, controlling, by the time control module, the time for applying the polarity-reversed DC voltage by the power supply moduleto the loading module to be shorter than the preset time.
